(19) United States
(12) Patent Application Publication
(10) Pub. No.: US 2026/0125622 A1
(43) Pub. Date: May 7, 2026

(54) SEMICONDUCTOR DEVICE CLEANING SOLUTION AND METHOD FOR PREPARING SAME

(71) Applicant: DONGWOO FINE-CHEM CO., LTD., Iksan-si (KR)

(72) Inventors: Sung-Ho BAEK, Iksan-si (KR); Seung-Pil HAN, Iksan-si (KR); Kyung-Hwa CHO, Iksan-si (KR); Baek-Hyun CHO, Iksan-si (KR); Seung-Hyeok IM, Iksan-si (KR)

(73) Assignee: DONGWOO FINE-CHEM CO., LTD., Iksan-si (KR)

(21) Appl. No.: 19/377,340

(22) Filed: Nov. 3, 2025

(30) Foreign Application Priority Data
Nov. 6, 2024 (KR) 10-2024-0156053

(51) Int. Cl. C11D 3/39; B01D 39/16; C11D 3/12; C11D 3/20; C11D 11/00; H01L 21/02

(52) U.S. Cl. CPC C11D 3/3942; B01D 39/16; C11D 3/1206; C11D 3/2034; C11D 11/0094; H10P 70/20

(57) ABSTRACT

The present disclosure relates to a semiconductor device cleaning solution comprising a phenol compound at 10 ppb or less and having a ratio of a plasma generation number per pulsed laser irradiation number by a laser-induced breakdown detection method of less than 2%, and relates to a high-purity semiconductor device cleaning solution capable of suppressing the generation of residues on the cleaning target surface during cleaning of the semiconductor devices by effectively controlling phenol compounds that are inevitably generated in the semiconductor device cleaning solution preparation process and a method for preparing the same.

### CROSS-REFERENCE TO RELATED APPLICATION(S)

This application claims the benefit under 35 USC 119(a) of Korean Patent Application No. KR 10-2024-0156053, filed on Nov. 6, 2024 in the Korean Intellectual Property Office, the disclosure of which is incorporated herein by reference in its entirety.

### TECHNICAL FIELD

The present disclosure relates to a semiconductor device cleaning solution and a method for preparing the same.

### BACKGROUND ART

In the manufacturing of highly integrated semiconductor devices, a conductive thin film, such as a metal film that serves as a conductive wiring material, or an interlayer insulating film for the purpose of performing insulation between conductive thin films, is formed on a device such as a wafer, then a photoresist is uniformly applied to the surface of the interlayer insulating film to prepare a photosensitive layer, exposure is selectively performed thereon, and development treatment is performed thereon to fabricate a desired resist pattern. Subsequently, a dry etching treatment is performed on the interlayer insulating film using this resist pattern as a mask, thereby forming a desired pattern on the thin film. In addition, a process is generally employed in which residues, etc. generated by the resist pattern and the dry etching treatment are completely removed by an ashing method using oxygen plasma, a cleaning method using a cleaning solution, or the like.

At this time, hydrogen peroxide and the like are used as cleaning solutions, and in particular, hydrogen peroxide is highly soluble in water, ethanol, and ether, and in aqueous solutions, some hydrogen ions are dissociated to exhibit weak acidity and strong oxidizing power, so it is used as an oxidation reaction agent, or the like in various fields. In particular, hydrogen peroxide is used for cleaning semiconductor wafers and etching during semiconductor and display manufacturing processes. In this case, high-purity hydrogen peroxide with extremely limited impurities is required.

However, since, when using commercially available hydrogen peroxide as is, impurity concentrations are high within hydrogen peroxide, resulting in damage and the like of semiconductors, not only the production of high-quality products is difficult, but also defects occur in which hydrogen peroxide remains as residues on the cleaning target surface due to agglomeration between impurities and nanoparticles in the harsh environment of the semiconductor device cleaning process, but the descriptions for causes and countermeasures for the defects remain inadequate.

Meanwhile, U.S. Pat. No. 8,715,613 discloses a method for producing high-purity hydrogen peroxide. However, the purified hydrogen peroxide solution still has high concentrations of impurities, such as phenol compounds, etc., which not only causes a problem of falling short of the purity required for fine chemical fields, but also does not solve the problem of the generation of residues on the cleaning target surface during cleaning of the semiconductor devices.

Therefore, there is a need for the development of a semiconductor device cleaning solution and its preparation method, the semiconductor device cleaning solution that meets the purity required in fine chemical fields such as the semiconductor industry field and the like, and suppresses the generation of residues on the cleaning target surface during cleaning of the semiconductor devices.

### RELATED ART DOCUMENT

### Patent Document

(Patent Document 1) U.S. Pat. No. 8,715,613

### DISCLOSURE

### Technical Problem

The present disclosure is for providing a semiconductor device cleaning solution and a method for preparing the same, the semiconductor device cleaning solution which can suppress the generation of residues on the cleaning target surface during cleaning of the semiconductor devices by effectively controlling phenol compounds that are inevitably generated in the semiconductor device cleaning solution preparation process.

However, the problems to be solved by the present disclosure are not limited to the problems mentioned above, and other problems not mentioned will be clearly understood by those skilled in the art from the description below.

### Technical Solution

In order to solve the problems, the present disclosure provides a semiconductor device cleaning solution comprising a phenol compound at 10 ppb or less and having a ratio of a plasma generation number per pulsed laser irradiation number by a laser-induced breakdown detection method of less than 2%.

The phenol compound may be one or more selected from the group consisting of phenol, methyl phenol, ethyl phenol, and isopropyl phenol.

The phenol compound may be contained at 0.1 ppb or more to 10 ppb or less.

The semiconductor device cleaning solution may have a ratio of a plasma generation number per pulsed laser irradiation number of less than 1.8%.

The semiconductor device cleaning solution may be hydrogen peroxide.

The nanoparticles present in the semiconductor device cleaning solution may be one or more selected from the group consisting of silver (Ag), calcium (Ca), nickel (Ni), silicon (Si), molybdenum (Mo), iron (Fe), and oxides of these metal particles.

The semiconductor device cleaning solution is a semiconductor device cleaning solution prepared by a preparation method comprising: a primary filtering process and a secondary filtering process, wherein the secondary filtering process may be performed using a filter formed of one or more selected from the group consisting of PTFE and UPE materials.

Furthermore, the present disclosure relates to a method for preparing the semiconductor device cleaning solution, the method comprising: a primary filtering process; and a secondary filtering process, wherein the secondary filtering process is performed using a filter formed of one or more selected from the group consisting of PTFE and UPE materials.

### Advantageous Effects

The present disclosure may provide a high-purity semiconductor device cleaning solution capable of suppressing the generation of residues on the cleaning target surface during cleaning of the semiconductor devices by effectively controlling phenol compounds that are inevitably generated in the semiconductor device cleaning solution preparation process.

Further, the present disclosure may provide a method for preparing the semiconductor device cleaning solution.

### Specific Details for Carrying Out the Invention

The present disclosure relates to a semiconductor device cleaning solution comprising a phenol compound at 10 ppb or less and having a ratio of a plasma generation number per pulsed laser irradiation number by a laser-induced breakdown detection method of less than 2%, and a method for preparing the same. According to the present disclosure, a high-purity semiconductor device cleaning solution capable of suppressing the generation of residues on the cleaning target surface during cleaning of the semiconductor devices by effectively controlling phenol compounds that are inevitably generated in the semiconductor device cleaning solution preparation process may be provided.

More specifically, when using the semiconductor device cleaning solution of the present disclosure, the defects in which residues remain on the cleaning target surface can be minimized even when the semiconductor device cleaning solution passes through a harsh environment during the semiconductor device cleaning process.

The semiconductor device in the present disclosure is not particularly limited as long as it is an object recognized as a semiconductor device in the art, and specifically, the semiconductor device may be a wafer and/or a pattern formed thereon.

In the present disclosure, the harsh environment may be an environment maintained at a temperature of 60° C. to 150° C. for 1 to 10 hours, but is not limited thereto.

The terms “comprises,” “comprising,” “includes,” “including,” “has” and/or “having” used in this specification are used in a sense that they do not exclude the presence or addition of one or more other components, steps, operations and/or devices other than the components, steps, operations and/or devices mentioned.

In this specification, “ppb” means “parts per billion” and “ppt” means “parts per trillion.”

### <Semiconductor Device Cleaning Solution>

The semiconductor device cleaning solution of the present disclosure comprises a phenol compound at 10 ppb or less and has a ratio (breakdown probability (BDP)) of a plasma generation number per pulsed laser irradiation number by a laser-induced breakdown detection (LIBD) method of less than 2%. Accordingly, a high-purity semiconductor device cleaning solution capable of suppressing the generation of residues on the cleaning target surface during cleaning of the semiconductor devices by effectively controlling phenol compounds that are inevitably generated in the semiconductor device cleaning solution preparation process may be provided.

According to one embodiment of the present disclosure, the semiconductor device cleaning solution may be hydrogen peroxide, but is not limited thereto.

### Phenol Compound

The semiconductor device cleaning solution of the present disclosure comprises a phenol compound at 10 ppb or less, preferably 0.1 ppb or more to 10 ppb or less.

The phenol compound refers to a compound produced from a degradation product of the working solution used in the anthraquinone method as a method for preparing a semiconductor device cleaning solution, and/or the resin and/or filter used in the process of purifying the prepared semiconductor device cleaning solution, and the phenol compound has an impact of causing defects such as residues to be generated on the surfaces of semiconductor devices cleaned with the semiconductor device cleaning solution in the aspect of promoting the aggregation of nanoparticles present in the semiconductor device cleaning solution.

The phenol compound includes phenol, methyl phenol, ethyl phenol, and isopropyl phenol, but is not limited thereto.

The semiconductor device cleaning solution of the present disclosure is preferable in the aspect that residues are not generated on the surface of the cleaning target by controlling the phenol compound so that it is contained in the above range, thereby making it difficult to form agglomerates with the nanoparticles contained in the semiconductor device cleaning solution.

### Laser-Induced Breakdown Detection Method

The semiconductor device cleaning solution of the present disclosure has a ratio (breakdown probability, hereinafter it is referred to as a BDP value) of a plasma generation number per pulsed laser irradiation number by a laser-induced breakdown detection method (hereinafter it is referred to as LIBD method) of less than 2%, preferably less than 1.8%.

The LIBD method of the present disclosure is according to the principle that when a pulsed laser is irradiated on nanoparticles contained in a liquid solution, the particles generate the multiphoton absorption effect, and multiple photons stimulate a single atom. At this time, the energy level is transited to an excited state, and the destabilized atoms emit various energies such as light, shock waves, sound, etc. while returning to the ground state, and at this time, signals such as emitted light CCD images, shock waves, or sounds are detected. Nanoparticles contained in the semiconductor device cleaning solution can be detected using such an LIBD method.

According to the LIBD method of the present disclosure, existing particle size analysis methods utilizing a light scattering method can improve limitations due to reduced sensitivity to nanoparticle size, etc. In particular, according to the present disclosure, all solid components up to 2 nm in size can be detected very accurately with them distinguished from air.

The size may include a diameter and a radius in the case of spherical particles, and a length and the like of the longest direction in the case of needle-shaped particles, but is not limited thereto.

Meanwhile, the BDP value obtained by the LIBD method represents the ratio of energy release, specifically the number of times plasma is generated, to the number of pulsed laser irradiations, and the BDP value increases with the content of solid components such as nanoparticles and the like in the semiconductor device cleaning solution being increased. Further, since the higher the intensity of a pulsed laser irradiated, the better plasma is generated, leading to a higher BDP value, it is desirable to set a reference for the pulsed laser intensity.

According to one embodiment of the present disclosure, the LIBD method utilized an analytical device manufactured with reference to the literature, Part. Part. Syst. Charact. 22 (2005) 181-191. The BDP value of the present disclosure calculated by the LIBD method was based on the pulsed laser intensity at which the BDP value of a standard reagent containing 20 nm-sized polystyrene particles (Themo SCIENTIFIC Microgenics Corporation) added to ultrapure water at a concentration of 1 ppt reached 2%.

According to one embodiment of the present disclosure, the nanoparticles present in the semiconductor device cleaning solution may be one or more selected from the group consisting of metal particles and oxides of the metal particles. Specifically, the metal particles may be one or more selected from the group consisting of silver (Ag), calcium (Ca), nickel (Ni), silicon (Si), molybdenum (Mo), and iron (Fe), but are not limited thereto.

According to one embodiment of the present disclosure, the semiconductor device cleaning solution is a semiconductor device cleaning solution prepared by a preparation method comprising: a primary filtering process; and a secondary filtering process, and the secondary filtering process may be performed using a filter formed of a polytetrafluoroethylene (PTFE) and/or an ultrahigh molecular weight polyethylene (UPE) material. The pore size of the filter may be 1 to 3 nm, preferably 1 to 2 nm, and most preferably 2 nm, and the number of filtration cycles performed through the filter may be 1 to 5 times, and preferably 1 to 3 times.

### <Method for Preparing a Semiconductor Device Cleaning Solution>

The present disclosure provides a method for preparing the semiconductor device cleaning solution described above. The method for preparing the semiconductor device cleaning solution of the present disclosure is not particularly limited as long as it is a method or step capable of preparing a semiconductor device cleaning solution comprising a phenol compound at 10 ppb or less and having a ratio of a plasma generation number per pulsed laser irradiation number by a laser-induced breakdown detection method of less than 2%.

According to one embodiment of the present disclosure, the method for preparing the semiconductor device cleaning solution comprises: a primary filtering process; and a secondary filtering process, and the secondary filtering process may be performed using a filter formed of PTFE and/or UPE material. The pore size of the filter may be 1 to 3 nm, preferably 1 to 2 nm, and most preferably 2 nm, and the number of filtration cycles performed through the filter may be 1 to 5 times, and preferably 1 to 3 times. More specifically, the method for preparing a semiconductor device cleaning solution is performed through a purification apparatus comprising a purification tower provided with an inlet pipe and a gas injection pipe, and a discharge pipe provided at the rear end of the purification tower, and may comprise steps of: (a) injecting an unpurified hydrogen peroxide solution into the purification tower through the inlet pipe and passing the unpurified hydrogen peroxide solution through a hybrid ion exchange resin; (b) purifying hydrogen peroxide through a primary filtering process and a secondary filtering process, wherein the secondary filtering process is performed using a filter formed of PTFE and/or UPE material; and (c) discharging the hydrogen peroxide solution through a discharge pipe that is connected to the lower end portion of the purification tower and includes a liquid level maintenance pipe.

When preparing the semiconductor device cleaning solution through the method, it is desirable in the aspect that it can stably discharge the gas generated by the reaction between hydrogen peroxide and the hybrid ion exchange resin to lower the risk of explosion, thereby improving the stability of the purification process for the semiconductor device cleaning solution.

The unpurified hydrogen peroxide solution contains various impurities, and typically, a cation exchange resin to remove cationic impurities, and an anion exchange resin for removing anionic impurities are used respectively. Further, in order to increase process efficiency by removing cationic and anionic impurities at the same time, a hybrid ion exchange resin in which the cation exchange resin and the anion exchange resin are mixed may be used. However, since the specific gravities of the cation exchange resin and the anion exchange resin are different from each other, it is difficult to prevent layer separation after mixing from occurring by conventional typical stirring methods.

The method for preparing a semiconductor device cleaning solution of the present disclosure is characterized by producing a hybrid ion exchange resin through a bubbling process in the aspect for preventing layer separation of the hybrid ion exchange resin, and more specifically, the hybrid ion exchange resin may be produced by injecting gas through the gas injection pipe to perform bubbling after introducing a mixture of a cation exchange resin, an anion exchange resin, and water into the purification tower.

In this way, the method for preparing a semiconductor device cleaning solution of the present disclosure is desirable in the aspect that a hybrid ion exchange resin is produced through a bubbling process of the cation exchange resin and anion exchange resin, thereby preventing layer separation of the cation exchange resin and anion exchange resin and reducing ion re-elution during the purification process to enable the generation of nanoparticles to be minimized and the generation of phenol compounds to be controlled.

In addition, it is preferable to maintain the liquid level height of the hydrogen peroxide solution within the purification tower to the height of the hybrid ion exchange resin or higher so that a portion of the hybrid ion exchange resin within the purification tower is not exposed and dried without being submerged in the hydrogen peroxide solution.

To this end, the discharge pipe includes a liquid level maintenance pipe, and the liquid level height of the hydrogen peroxide solution may be maintained to the height of the hybrid ion exchange resin or higher through the liquid level maintenance pipe.

The liquid level maintenance pipe refers to a portion of the discharge pipe including a U-shaped bent portion, wherein both ends of the liquid level maintenance pipe face the same direction, and the middle portion may have a bent shape so as to protrude in a direction different from the both ends, and the shape of the bent portion is not limited to a U-shape, but may include a U-deformed shape, a V-shape, and a V-deformed shape, but is not limited thereto.

The liquid level maintenance pipe preferably has a diameter of 50 to 100 mm in the aspect of pipe pressure loss, and it is preferable that the separation distance from the purification tower be within 20 m considering the cost aspect of the pipe and pressure loss.

Further, the liquid level maintenance pipe is preferably constructed of the same material as that of the purification tower.

The U-shaped bent portion faces upward, not toward the ground, and its uppermost portion becomes the maximum height of the liquid level maintenance pipe. The purified hydrogen peroxide solution transferred through the liquid level maintenance pipe passes through a section where it is transferred in the opposite direction in which gravity acts before passing through the U-shaped bent portion which is the maximum height.

Accordingly, if the liquid level height of the hydrogen peroxide solution within the purification tower is higher than or equal to the maximum height of the liquid level maintenance pipe, the purified hydrogen peroxide solution discharged from the purification tower can pass through the liquid level maintenance pipe. Conversely, if the liquid level height of the hydrogen peroxide solution within the purification tower is lower than the maximum height of the liquid level maintenance pipe, the purified hydrogen peroxide solution discharged from the purification tower cannot reach the maximum height of the liquid level maintenance pipe and thus cannot pass through the liquid level maintenance pipe.

Therefore, if the maximum height of the liquid level maintenance pipe is the height of the hybrid ion exchange resin within the purification tower or higher, the liquid level height of the hydrogen peroxide solution within the purification tower can also be maintained to be the height of the hybrid ion exchange resin or higher, thereby fundamentally preventing a portion of the hybrid ion exchange resin within the purification tower from being exposed and dried without being submerged into the hydrogen peroxide solution.

In this way, it is preferable in the aspect that the height of the hydrogen peroxide solution within the purification tower is allowed to be maintained to the height of the hybrid ion exchange resin or higher through the liquid level maintenance pipe so that sufficient time is secured for the hydrogen peroxide solution to pass through the hybrid ion exchange resin, thereby enabling the generation of nanoparticles to be minimized and the generation of a phenol compound to be controlled.

In particular, in the aspect for controlling the phenol compound to 10 ppb or less in the semiconductor device cleaning solution preparation method of the present disclosure, it is preferable that the method comprises altogether a feature in which the hydrogen peroxide solution in the step (a) is passed from the upper side to the lower side of the hybrid ion exchange resin, and the liquid level maintenance pipe in the step (c) has a maximum height of the height of the hybrid ion exchange resin or higher within the purification tower; and a feature in which the hybrid ion exchange resin through which the hydrogen peroxide solution in the step (a) is passed is prepared by injecting gas into a mixture of a cation exchange resin, an anion exchange resin, and water and bubbling it therein. When the semiconductor device cleaning solution is prepared by comprising only one of the above features without comprising the features altogether, it is preferable to perform the semiconductor device cleaning solution preparation method of the present disclosure by comprising the features altogether in the aspect of generating a problem that it is difficult to control the phenol compound generated during the preparation process to 10 ppb or less.

Hereinafter, specific Examples for implementing the present disclosure will be described specifically. However, the present disclosure is not limited to the Examples disclosed below, but can be implemented in various different forms, and these Examples are provided only to ensure that the disclosure of the present disclosure is complete and to fully inform those skilled in the art to which the present disclosure pertains of the scope of the invention, and the present disclosure is defined only by the scope of the claims.

### EXAMPLES AND COMPARATIVE EXAMPLES

### Example 1

A mixture of a cation exchange resin (functional group: sulfonic acid group; ion exchange capacity: 2.0 eq/L; effective acidity: pH 0 to 14), an anion exchange resin (functional group: quaternary ammonium group; ion exchange capacity: 1.0 eq/L; effective acidity: pH 1 to 14), and water (resistivity of 18.2 MΩ·cm) was introduced into a purification tower with an inner diameter of 700 mm and an internal height of 3600 mm, and air passing through a filtration device (filtration grade of 0.05 μm) was injected through a gas injection valve connected to the lower end portion of the purification tower at a pressure of 1.0 kgf/cm² for 24 hours to bubble the mixture, thereby producing a hybrid ion exchange resin to fill the purification tower with the hybrid ion exchange resin so that the hybrid ion exchange resin was filled to reach 33.3% (1200 mm) of the internal height of the purification tower. Thereafter, unpurified hydrogen peroxide solution (31%, impurity level of 10 ppb) was introduced through the inlet pipe at the top of the purification tower so that after the temperature was maintained to less than 15° C. and the hydrogen peroxide solution was allowed to pass through the hybrid ion exchange resin, filtering as a primary filtering process was performed twice with a filler with a pore size of 50 nm, and filtering as the secondary filtering process was performed three times with a filler with a pore size of 2 nm.

A semiconductor device cleaning solution was prepared by discharging the purified hydrogen peroxide solution at a flow rate of 1650 L/hr through a discharge pipe which was connected to the bottom of the purification tower and included a liquid level maintenance pipe with a maximum height of 1400 mm.

### Examples 2 and 3

Semiconductor device cleaning solutions were prepared in the same manner as in Example 1 except that the pore size and number of filtration cycles in the primary and secondary filtering processes were adjusted as shown in Table 1 below.

### Comparative Example 1

A semiconductor device cleaning solution was prepared in the same manner as in Example 1 except that filtering as the primary filtering process was performed three times using a filter with a pore size of 50 nm, the secondary filtering process was not performed, and the liquid level maintenance pipe connected to the bottom of the purification tower had a maximum height of 1,000 mm.

### Comparative Example 2

A semiconductor device cleaning solution was prepared in the same manner as in Example 1 except that filtering as the primary filtering process was performed once using a filter with a pore size of 50 nm, and the secondary filtering process was not performed.

### Comparative Example 3

A semiconductor device cleaning solution was prepared in the same manner as in Example 1 except that the pore size and number of filtration cycles in the primary filtering process and secondary filtering process were adjusted as shown in Table 1 below, and the hybrid ion exchange resin was produced by mixing the cation exchange resin and anion exchange resin were through mechanical stirring without a bubbling process in the process of producing the hybrid ion exchange resin.

TABLE 1

| | Primary filtering process | | Secondary filtering process | |
|---|---|---|---|---|
| | Filter | Number of | Filter | Number of |
| Hydrogen | Size | filtration | Size | filtration |
| peroxide | (nm) | cycles | (nm) | cycles |
| Example 1 | 50 | 2 | 2 | 3 |
| Example 2 | 50 | 2 | 2 | 2 |
| Example 3 | 50 | 1 | 2 | 1 |
| Comparative | 50 | 3 | Not | Not |
| Example 1 | | | performed | performed |
| Comparative | 50 | 1 | Not | Not |
| Example 2 | | | performed | performed |
| Comparative | 50 | 1 | 2 | 1 |
| Example 3 | | | | |

### Experimental Example

### (1) Measurement of the Content of Phenol Compound in Semiconductor Device Cleaning Solutions

The content of a phenol compound in each of the semiconductor device cleaning solutions prepared in the Examples and the Comparative Examples above was analyzed using a pyrolysis system and GC-MS equipment by concentrating the prepared semiconductor device cleaning solutions. A DB-5MS column (30 m×0.25 mm) was used, and the mass range was analyzed from m/z 30 to 700. The peak area of the pre-quantified phenol standard compound and the peak area of the corresponding standard compound in the semiconductor device cleaning solutions were comparatively measured, and the results are shown in Table 2 below based on the following criteria:
o: 10 ppb or less
X: More than 10 ppb

### (2) Measurement of the BDP Value of Semiconductor Device Cleaning Solutions Using the LIBD Method

After setting the pulsed laser intensity so that a BDP value became 2% using a reagent containing 20 nm-sized polystyrene particles (Themo SCIENTIFIC Microgenics Corporation) injected into ultrapure water at a concentration of 1 ppt as a standard reagent, BDP values of the semiconductor device cleaning solutions prepared in the Examples and the Comparative Examples above were measured by the LIBD method using an analytical instrument manufactured by referring to the literature (Part. Part. Syst. Charact. 22 (2005) 181-191), and the results are shown in Table 2 below.

### (3) Measurement of Numbers by Particle Sizes in Semiconductor Device Cleaning Solutions

For the semiconductor device cleaning solutions prepared in the Examples and the Comparative Examples above, the total numbers of nanoparticles (ea) of 20 nm or more, 30 nm or more, and 60 nm or more per unit volume (ml) were measured using LPC19F (RION), and the results are shown in Table 2 below.

TABLE 2
Semiconductor

| device cleaning | Phenol | LIBD method | LPC (ea/ml) | | |
|---|---|---|---|---|---|
| solution | compound | BDP (%) | 20 nm | 30 nm | 60 nm |
| Example 1 | ◯ | 0.9 | 3 | 1 | 0 |
| Example 2 | ◯ | 1.2 | 5 | 1 | 0 |
| Example 3 | ◯ | 1.8 | 6 | 2 | 0 |
| Comparative | X | 3.5 | 10 | 4 | 0 |
| Example 1 | | | | | |
| Comparative | ◯ | 10.3 | 23 | 11 | 0 |
| Example 2 | | | | | |
| Comparative | X | 1.8 | 6 | 2 | 0 |
| Example 3 | | | | | |

(4) Measurement of the Numbers of Particles by Sizes generated under Harsh Conditions

For the semiconductor device cleaning solutions prepared in the Examples and the Comparative Examples above, nanoparticles were added so that the nanoparticles had a concentration of 5 ppt as shown in Table 3 below, and then the numbers of particles by sizes were measured using LPC19F (RION) in the same manner as described above. After passing through a harsh test of stirring at 80° C. conditions for 6 hours, the numbers of particles by sizes were re-measured, and the results are shown in Table 3 below.

TABLE 3

| | Semiconductor | | | | LPC (before | | | LPC (after | | |
|---|---|---|---|---|---|---|---|---|---|---|
| | device | Addition of nanoparticles | | | harsh test) | | | harsh test) | | |
| | cleaning | | Size | Concentration | 20 | 30 | 60 | 20 | 30 | 60 |
| | solution | Type | (nm) | (ppt) | nm | nm | nm | nm | nm | nm |
| Experimental | Example 1 | Ag | 2 | 5 | 3 | 1 | 0 | 3 | 1 | 0 |
| Example 1 | | | | | | | | | | |
| Experimental | Example 1 | Fe₃O₄ | 15 | 5 | 3 | 1 | 0 | 3 | 1 | 0 |
| Example 2 | | | | | | | | | | |
| Experimental | Example 2 | Ag | 2 | 5 | 5 | 1 | 0 | 5 | 1 | 0 |
| Example 3 | | | | | | | | | | |
| Experimental | Example 2 | Fe₃O₄ | 15 | 5 | 5 | 1 | 0 | 5 | 1 | 0 |
| Example 4 | | | | | | | | | | |
| Experimental | Example 3 | Ag | 2 | 5 | 6 | 2 | 0 | 6 | 2 | 0 |
| Example 5 | | | | | | | | | | |
| Experimental | Example 3 | Fe₃O₄ | 15 | 5 | 6 | 2 | 0 | 6 | 2 | 0 |
| Example 6 | | | | | | | | | | |
| Comparative | Comparative | Ag | 2 | 5 | 10 | 4 | 0 | 27 | 12 | 5 |
| Experimental | Example 1 | | | | | | | | | |
| Example 1 | | | | | | | | | | |
| Comparative | Comparative | Fe₃O₄ | 15 | 5 | 10 | 4 | 0 | 55 | 25 | 11 |
| Experimental | Example 1 | | | | | | | | | |
| Example 2 | | | | | | | | | | |
| Comparative | Comparative | Ag | 2 | 5 | 23 | 11 | 0 | 64 | 37 | 23 |
| Experimental | Example 2 | | | | | | | | | |
| Example 3 | | | | | | | | | | |
| Comparative | Comparative | Fe₃O₄ | 15 | 5 | 23 | 11 | 0 | 119 | 52 | 39 |
| Experimental | Example 2 | | | | | | | | | |
| Example 4 | | | | | | | | | | |
| Comparative | Comparative | Ag | 2 | 5 | 6 | 2 | 0 | 15 | 7 | 3 |
| Experimental | Example 3 | | | | | | | | | |
| Example 5 | | | | | | | | | | |
| Comparative | Comparative | Fe₃O₄ | 15 | 5 | 6 | 2 | 0 | 32 | 17 | 9 |
| Experimental | Example 3 | | | | | | | | | |
| Example 6 | | | | | | | | | | |

Referring to Table 2 above, it can be confirmed that the semiconductor device cleaning solutions according to Examples 1 to 3 of the present disclosure had low BDP numerical values of 1.8% or less as measured by the LIBD method, and the results of measuring the numbers of particles by sizes using LPC also showed that the numbers of nanoparticles of 20 nm or more were measured to be 6 or less per unit volume so that it can be confirmed that the numbers of nanoparticles inside the cleaning solutions were very small. As a result, it can be confirmed through Table 3 that there was no change in the numbers of nanoparticles per unit volume even after administering nanoparticles to the semiconductor device cleaning solutions of Examples 1 to 3 and then subjecting them to a harsh test corresponding to the semiconductor device cleaning process.

In contrast, the semiconductor device cleaning solutions according to Comparative Examples 1 and 2 of the present application were prepared without going through a secondary filtering process, and thus the BDP values measured by the LIBD method had high numerical values of 3.5% or more, and the results of measuring the numbers of the particles by sizes using LPC also showed that the numbers of nanoparticles of 20 nm or more were measured to be 10 or more per unit volume so that it can be confirmed that the numbers of the nanoparticles inside the cleaning solutions were greater than those of Examples. In addition, the semiconductor device cleaning solution according to Comparative Example 1 was prepared through a preparation device in which the maximum height of the liquid level maintenance pipe was formed to be lower than the height of the ion exchange resin in the semiconductor device cleaning solution preparation process, and it can be confirmed that the phenol compound contained in the semiconductor device cleaning solutions exceeded 10 ppb. As a result, after administering nanoparticles to the semiconductor device cleaning solutions of Comparative Examples 1 and 2 and then subjecting it to a harsh test corresponding to the semiconductor device cleaning process, the nanoparticles of 20 nm or more were generated in large numbers of 27 or more per unit volume so that it can be confirmed that they affected the surface of the semiconductor device compared to the Examples.

Although both the primary and secondary filtering processes were performed, the semiconductor device cleaning solution according to Comparative Example 3 was prepared by performing a filtering process through a hybrid ion exchange resin that did not undergo a bubbling process in the semiconductor device cleaning solution preparation process, and the nanoparticles of 20 nm or more were included in numbers of 6 per unit volume, but the phenol compound contained in the semiconductor device cleaning solution exceeded 10 ppb so that it can be confirmed that nanoparticles of 20 nm or more after the harsh test were generated in large numbers of 15 or more per unit volume.

1. A semiconductor device cleaning solution comprising a phenol compound at 10 ppb or less and having a ratio of a plasma generation number per pulsed laser irradiation number by a laser-induced breakdown detection method of less than 2%.

2. The semiconductor device cleaning solution of claim 1, wherein the phenol compound is one or more selected from the group consisting of phenol, methyl phenol, ethyl phenol, and isopropyl phenol.

3. The semiconductor device cleaning solution of claim 1, wherein the phenol compound is contained at 0.1 ppb or more to 10 ppb or less.

4. The semiconductor device cleaning solution of claim 1, wherein the semiconductor device cleaning solution has a ratio of a plasma generation number per pulsed laser irradiation number of less than 1.8%.

5. The semiconductor device cleaning solution of claim 1, wherein the semiconductor device cleaning solution is hydrogen peroxide.

6. The semiconductor device cleaning solution of claim 1, wherein the nanoparticles present in the semiconductor device cleaning solution are one or more selected from the group consisting of silver (Ag), calcium (Ca), nickel (Ni), silicon (Si), molybdenum (Mo), iron (Fe), and oxides of these metal particles.

7. A semiconductor device cleaning solution prepared by a preparation method comprising: a primary filtering process and a secondary filtering process, wherein the secondary filtering process is performed using a filter formed of one or more selected from the group consisting of PTFE and UPE materials.

8. A method for preparing the semiconductor device cleaning solution of claim 1, the method comprising: a primary filtering process; and a secondary filtering process, wherein the secondary filtering process is performed using a filter formed of one or more selected from the group consisting of PTFE and UPE materials.
